(19) United States
(12) Patent Application Publication
(10) Pub. No.: US 2019/0174653 A1
(43) Pub. Date: Jun. 6, 2019

(54) LIQUID-COOLING HEAT DISSIPATING MODULE

(71) Applicant: AURAS Technology Co., Ltd., New Taipei City (TW)

(72) Inventors: MU-SHU FAN, New Taipei City (TW); CHE-CHIA CHANG, New Taipei City (TW); CHIEN-CHIH SU, New Taipei City (TW)

(21) Appl. No.: 15/866,524

(22) Filed: Jan. 10, 2018

(30) Foreign Application Priority Data
Dec. 6, 2017 (CN) 201711278068.6

(51) Int. Cl. H05K 7/20

(52) U.S. Cl. CPC H05K 7/20263; H05K 7/20272

(57) ABSTRACT

A liquid-cooling heat dissipating module includes a liquid-cooling radiator, a liquid-cooling head, a liquid pump, a first pipe, a second pipe and a shielding cover. The liquid-cooling radiator, the liquid-cooling head and the liquid pump are in fluid communication with each other through the first pipe, the second pipe and an external pump tube of the liquid pump. The liquid-cooling head is in thermal contact with a heat source. The liquid pump drives a fluid medium to circularly flow within the closed loop. At least a part of the liquid pump is sheltered by the shielding cover. Consequently, at least a portion of a sound generated by the liquid pump is obstructed from outputting to surroundings.

### FIELD OF THE INVENTION

The present invention relates to a heat dissipating device, and more particularly to a liquid-cooling heat dissipating module.

### BACKGROUND OF THE INVENTION

With increasing development of computers and various electronic products, people of the modern societies often spend lot of time in using computers and various electronic products. In case that the computer or the electronic product has been operated for a long time, the heat generated by the computer or the electronic product cannot be dissipated away quickly.

Generally, for most of the electronic products, thermal greases or heat sinks are attached on the heat generation components of the electronic products to absorb the heat from the heat generation components and dissipate the heat away. As known, the heat dissipating efficiency of using the thermal grease or the heat sink is usually unsatisfied. For solving this drawback, a liquid-cooling heat dissipating module has been disclosed.

FIG. 1 schematically illustrates the architecture of a conventional liquid-cooling heat dissipating module. As shown in FIG. 1, the liquid-cooling heat dissipating module 1 comprises a water-cooling radiator 11, a water-cooling head 12 and a water pump 13. Every two of the water-cooling radiator 11, the water-cooling head 12 and the water pump 13 are connected with each other through a pipe 14. Consequently, the water-cooling radiator 11, the water-cooling head 12 and the water pump 13 are in fluid communication with each other. The water-cooling head 12 is in thermal contact with a heat source (not shown) of an electronic product (not shown). Consequently, the heat is transferred from the heat source to the water-cooling head 12. A fluid medium (not shown) within the water-cooling head 12 is heated by the heat. The fluid medium flows to the low-temperature site of the liquid-cooling heat dissipating module 1 to perform the heat exchange. The water pump 13 drives the fluid medium to flow within a loop of the liquid-cooling heat dissipating module 1.

However, the liquid-cooling heat dissipating module 1 still has some drawbacks. For example, the operation of the water pump 13 may generate unpleasant noise. When the liquid-cooling heat dissipating module 1 is used to remove the heat from the electronic product, the user usually feels uncomfortable because of the noise. In other words, the liquid-cooling heat dissipating module needs to be further improved.

### SUMMARY OF THE INVENTION

For solving the drawbacks of the conventional technologies, the present invention provides a liquid-cooling heat dissipating module. At least a part of a liquid pump is sheltered by a shielding cover. Consequently, at least a portion of the sound generated by the liquid pump is obstructed from outputting to surroundings.

In accordance with an aspect of the present invention, there is provided a liquid-cooling heat dissipating module. The liquid-cooling heat dissipating module includes a liquid-cooling radiator, a liquid-cooling head, a first pipe, a liquid pump, a second pipe and a shielding cover. The liquid-cooling radiator includes a radiator main body, a radiator outlet and a radiator inlet. The liquid-cooling head is in thermal contact with a heat source. The liquid-cooling head includes a head main body, a head outlet and a head inlet. Two ends of the first pipe are connected with the head outlet of the liquid-cooling head and the radiator inlet of the liquid-cooling radiator, respectively. The liquid pump includes a pump main body, a pump outlet, a pump inlet and an external pump tube. Two ends of the external pump tube are connected with the pump outlet of the liquid pump and the head inlet of the liquid-cooling head, respectively. Two ends of the second pipe are connected with the pump inlet of the liquid pump and the radiator outlet of the liquid-cooling radiator, respectively. At least a part of the liquid pump is sheltered by the shielding cover, so that at least a portion of a sound generated by the liquid pump is obstructed from outputting to surroundings.

In an embodiment, the shielding cover includes a cover body and a buffering structure. The buffering structure is filled in a space between the cover body and the liquid pump.

In an embodiment, the buffering structure is a sound-absorbing foam structure or a sound-insulating foam structure.

In an embodiment, the liquid pump is fixed on the liquid-cooling head.

In an embodiment, the shielding cover is fixed on the liquid-cooling head.

In an embodiment, an outer periphery of the head main body of the liquid-cooling head includes at least one locking hole. When the at least a part of the liquid pump is sheltered by the shielding cover, at least one screwing element is penetrated through the at least one locking hole and tightened into the shielding cover, so that the shielding cover is fixed on the liquid-cooling head.

In an embodiment, the shielding cover is fixed on an object that is located outside the liquid-cooling heat dissipating module.

In an embodiment, the object is an electronic component with the heat source.

In an embodiment, an outer periphery of the shielding cover comprises at least one locking hole. When the at least a part of the liquid pump is sheltered by the shielding cover, at least one screwing element is penetrated through the at least one locking hole and tightened into the object, so that the shielding cover is fixed on the object.

In an embodiment, the shielding cover includes a first opening and a second opening. The external pump tube is penetrated through the first opening. The second pipe is penetrated through the second opening.

In an embodiment, the shielding cover further includes a third opening. The first pipe is penetrated through the third opening.

In an embodiment, the liquid-cooling heat dissipating module further includes a fan module. The fan module is located beside the liquid-cooling radiator.

From the above descriptions, the liquid-cooling heat dissipating module of the present invention is equipped with the shielding cover. At least a part of a liquid pump is sheltered by a shielding cover. Consequently, at least a portion of the sound generated by the liquid pump is obstructed from outputting to surroundings. Moreover, a buffering structure is arranged between the cover body of the shielding cover and the liquid pump to alleviate the noise to be outputted to the surrounding. The shielding cover is not restrictedly fixed on the liquid-cooling heat dissipating module. Alternatively, the shielding cover is fixed on an object that is located outside the liquid-cooling heat dissipating module. Consequently, the liquid-cooling heat dissipating module is more user-friendly.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 schematically illustrates the architecture of a conventional liquid-cooling heat dissipating module;

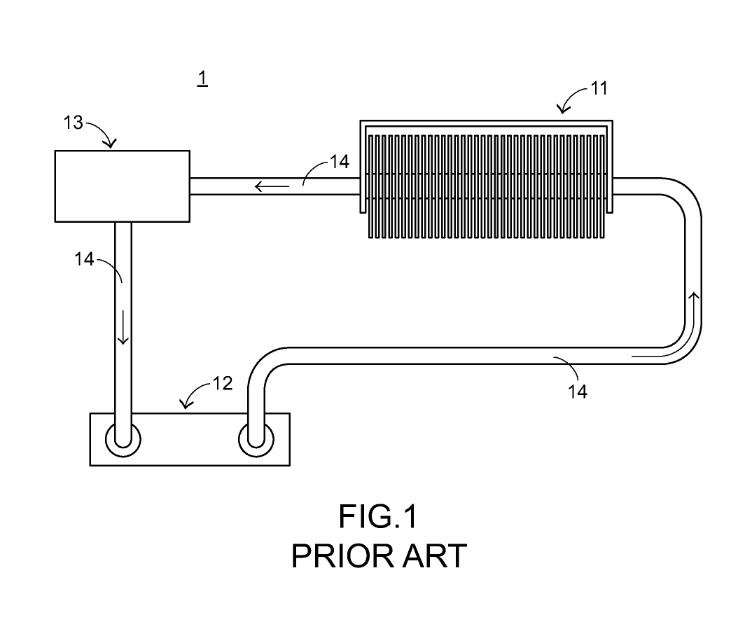

FIG. 2 schematically illustrates the architecture of a liquid-cooling heat dissipating module according to a first embodiment of the present invention;

FIG. 3 is a schematic perspective view illustrating a water-cooling head, a liquid pump and a shielding cover of the liquid-cooling heat dissipating module according to a first embodiment of the present invention;

FIG. 4 is a schematic exploded view illustrating the relationship between the water-cooling head, the liquid pump and the shielding cover of the liquid-cooling heat dissipating module as shown in FIG. 3 and taken along a viewpoint;

FIG. 5 is a schematic exploded view illustrating the relationship between the water-cooling head, the liquid pump and the shielding cover of the liquid-cooling heat dissipating module as shown in FIG. 3 and taken along another viewpoint;

FIG. 6 schematically illustrates the architecture of a liquid-cooling heat dissipating module according to a second embodiment of the present invention; and

FIG. 7 schematically illustrates the architecture of a liquid-cooling heat dissipating module according to a third embodiment of the present invention.

### DETAILED DESCRIPTION OF THE PREFERRED EMBODIMENT

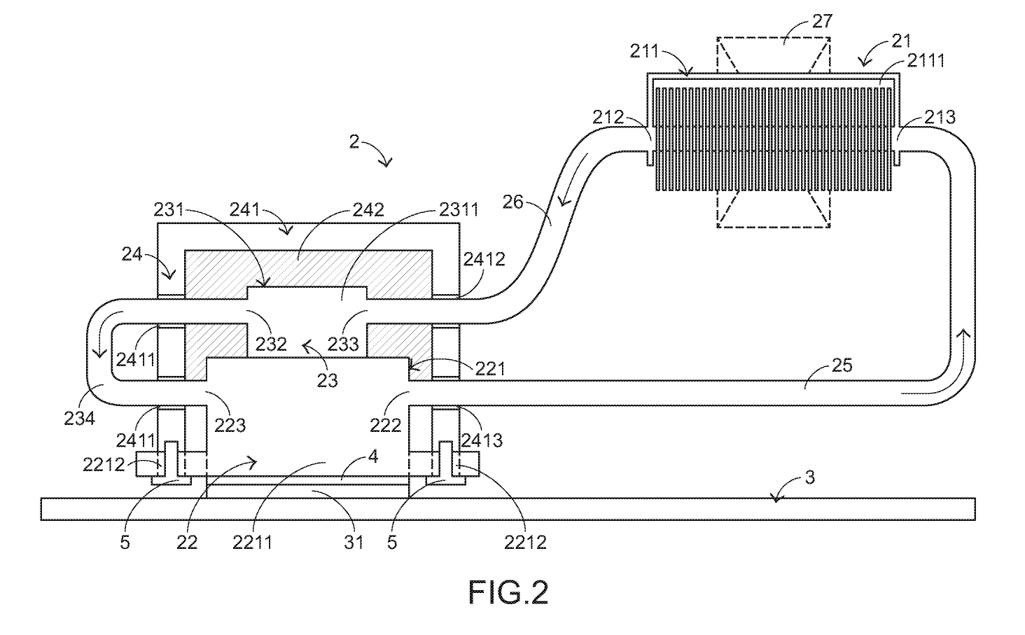

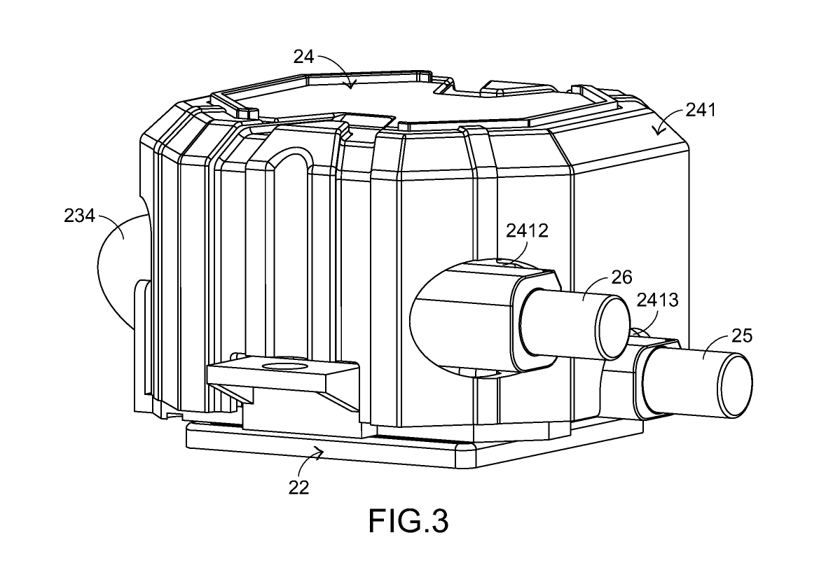

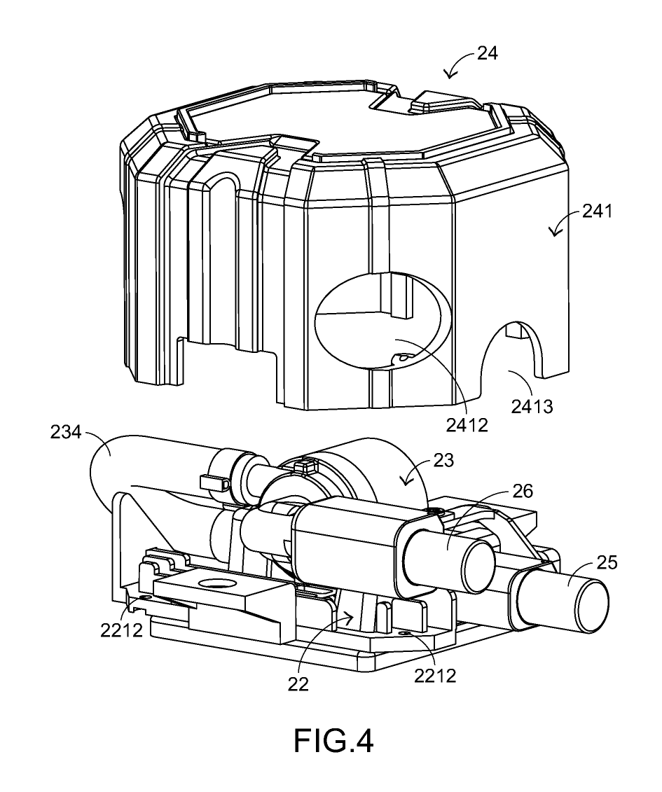

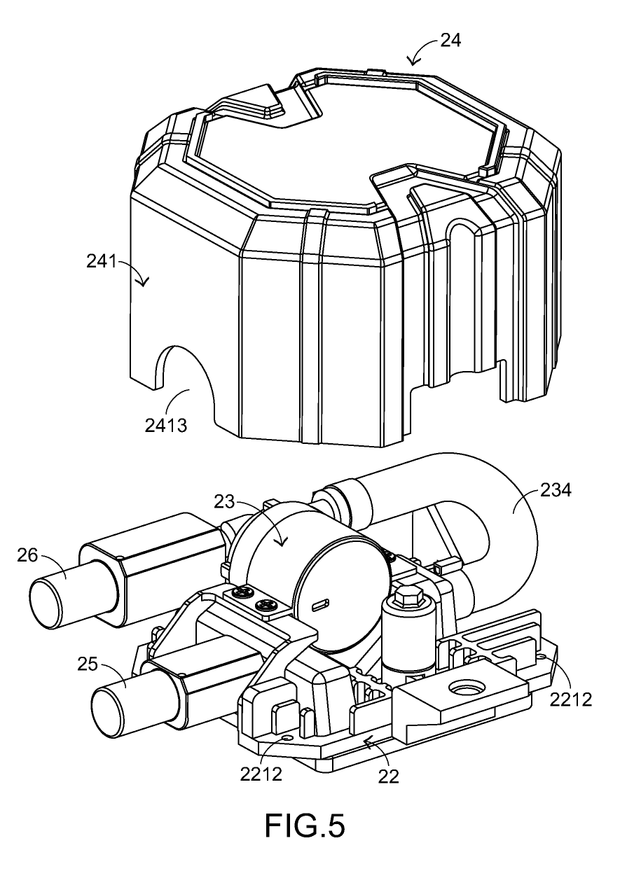

Please refer to FIGS. 2, 3, 4 and 5. FIG. 2 schematically illustrates the architecture of a liquid-cooling heat dissipating module according to a first embodiment of the present invention. FIG. 3 is a schematic perspective view illustrating a liquid-cooling head, a liquid pump and a shielding cover of the liquid-cooling heat dissipating module according to a first embodiment of the present invention. FIG. 4 is a schematic exploded view illustrating the relationship between the liquid-cooling head, the liquid pump and the shielding cover of the liquid-cooling heat dissipating module as shown in FIG. 3 and taken along a viewpoint. FIG. 5 is a schematic exploded view illustrating the relationship between the liquid-cooling head, the liquid pump and the shielding cover of the liquid-cooling heat dissipating module as shown in FIG. 3 and taken along another viewpoint.

In an embodiment, the liquid-cooling heat dissipating module 2 comprises a liquid-cooling radiator 21, a liquid-cooling head 22, a liquid pump 23, a shielding cover 24, a first pipe 25 and a second pipe 26. The liquid-cooling radiator 21 comprises a radiator main body 211, a radiator outlet 212 and a radiator inlet 213. The liquid-cooling head 22 comprises a head main body 221, a head outlet 222 and a head inlet 223. The liquid pump 23 comprises a pump main body 231, a pump outlet 232, a pump inlet 233 and an external pump tube 234. The two ends of the first pipe 25 are connected with the head outlet 222 of the liquid-cooling head 22 and the radiator inlet 213 of the liquid-cooling radiator 21, respectively. The two ends of the second pipe 26 are connected with the pump inlet 233 of the liquid pump 23 and the radiator outlet 212 of the liquid-cooling radiator 21, respectively. The two ends of the external pump tube 234 are connected with the pump outlet 232 of the liquid pump 23 and the head inlet 223 of the liquid-cooling head 22, respectively. Consequently, a chamber 2211 of the head main body 221, the first pipe 25, a chamber 2111 of the radiator main body 211, the second pipe 26, a chamber 2311 of the pump main body 231 and the external pump tube 234 are in fluid communication with each other to define a closed loop.

Moreover, a liquid medium (not shown) is filled within the closed loop. The liquid pump 23 drives the fluid medium to circularly flow within the closed loop. When the liquid-cooling head 22 is in thermal contact with a heat source 31, the liquid medium within the chamber 2211 of the head main body 221 is heated and its temperature is increased. The heated liquid medium is introduced into the chamber 2111 of the radiator main body 211 through the first pipe 25. Due to the heat exchange, the temperature of the liquid medium is decreased. The liquid medium with the decreased temperature is driven by the liquid pump 23 and introduced into the chamber 2211 of the head main body 221 through the external pump tube 234. The liquid medium within the closed loop is circularly driven to flow along the loop. Consequently, the heat is transferred from the high-temperature site to the low-temperature site, and cooling efficacy is enhanced.

In this context, the thermal contact is the contact via thermal conduction. In accordance with the present invention, the liquid-cooling head 22 and the heat source 31 are in direct contact with each other or in indirect contact with each other. In some embodiments, the liquid-cooling head and the heat source are close to each other but not contacted with each other. In case that the liquid-cooling head 22 and the heat source 31 are in direct contact with each other, the surface of the liquid-cooling head 22 is directly attached on the surface of the heat source 31. In case that the case and the heat source 31 are in indirect contact with each other, a thermal conductive medium 4 such as thermal grease (not shown) is arranged between the liquid-cooling head 22 and the heat source 31. The indirect contact between the liquid-cooling head 22 and the heat source 31 through the thermal conductive medium 4 is shown in FIG. 2.

In an embodiment, the heat source 31 is an electronic unit on an electronic component 3. For example, the electronic component 3 is a circuit board, and the electronic unit is a chip on the circuit board. The liquid pump 23 is an external pump that is standalone and can be operated individually. The liquid pump 23 is fixed on the liquid-cooling head 22. It is noted that the type of the heat source 31, the type of the electronic component 3, the type of the liquid pump 23 and the way of fixing the liquid pump 23 are not restricted. Preferably but not exclusively, the liquid-cooling heat dissipating module 2 further comprises a fan module 27. The fan module 27 is located beside the liquid-cooling radiator 21. By using the fan module 27, the heat from the liquid medium to the liquid-cooling radiator 21 is dissipated away quickly. Consequently, the heat dissipating efficacy is enhanced.

As mentioned above, the operation of the liquid pump 23 may generate noise. In this embodiment, the shielding cover 24 is employed to shelter a part of the liquid pump 23. During the operation of the liquid pump 23, a portion of the sound is obstructed from outputting to the surroundings. Moreover, the shielding cover 24 comprises a cover body 241 and a buffering structure 242. The liquid-cooling head 22 and the liquid pump 23 fixed on the liquid-cooling head 22 are sheltered by the cover body 241. Preferably but not exclusively, the buffering structure 242 is a sound-absorbing foam structure or a sound-insulating foam structure. The buffering structure 242 is filled in the space between the cover body 241, the liquid-cooling head 22 and the liquid pump 23. An outer periphery of the head main body 221 of the liquid-cooling head 22 comprises plural locking holes 2212. When the liquid-cooling head 22 and the liquid pump 23 are sheltered by the cover body 241, plural screwing elements 5 are penetrated through the corresponding locking holes 2212 and tightened into the shielding cover 24. Consequently, the shielding cover 24 is fixed on the liquid-cooling head 22. It is noted that the fixed position and the fixing method of the shielding cover 24 and the filled range of the buffering structure 242 are not restricted. Those skilled in the art may realize that numerous modifications and alterations may be made while retaining the teachings of the invention. For example, in another embodiment, the structure of the shielding cover 24 is modified. After the screwing elements 5 are penetrated through the shielding cover 24, the screwing elements 5 are penetrated through the corresponding locking holes 2212 of the head main body 221.

In this embodiment, the cover body 241 of the shielding cover 24 further comprises a first opening 2411, a second opening 2412 and a third opening 2413. When the liquid-cooling head 22 and the liquid pump 23 are sheltered by the cover body 241, the external pump tube 234 of the liquid pump 23 are penetrated through the first opening 2411, the second pipe 26 is penetrated through the second opening 2412, and the first pipe 25 is penetrated through the third opening 2413. The first opening 2411, the second opening 2412 and the third opening 2413 are close-type openings or open-type openings. Moreover, these structures are helpful to assist in positioning the liquid-cooling head 22, the liquid pump 23, the first pipe 25 and the second pipe 26.

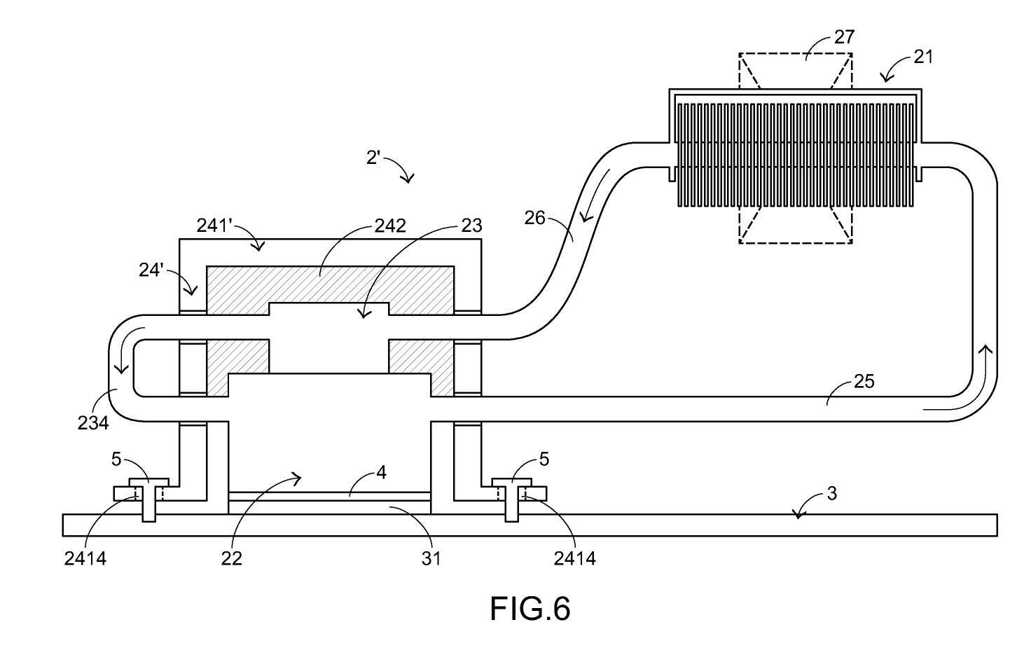

FIG. 6 schematically illustrates the architecture of a liquid-cooling heat dissipating module according to a second embodiment of the present invention. The components of the liquid-cooling heat dissipating module 2′ of this embodiment that are similar to those of the first embodiment are not redundantly described herein. In comparison with the first embodiment, the shielding cover 24′ is fixed on an object that is located outside of the liquid-cooling heat dissipating module 2′.

In an embodiment, the object is an electronic component 3 with the heat source 31. For example, the electronic component 3 is a circuit board, and the heat source 31 is a chip on the circuit board. An outer periphery of the cover body 241′ of the shielding cover 24′ comprises plural locking holes 2414. When the liquid-cooling head 22 and the liquid pump 23 are sheltered by the cover body 241′, plural screwing elements 5 are penetrated through the corresponding locking holes 2414 and tightened into the electronic component 3. Consequently, the shielding cover 24′ is fixed on the electronic component 3. It is noted that the type of the object, the fixed position and the fixing method of the shielding cover 24′ and the filled range of the buffering structure 242 are not restricted. Those skilled in the art may realize that numerous modifications and alterations may be made while retaining the teachings of the invention.

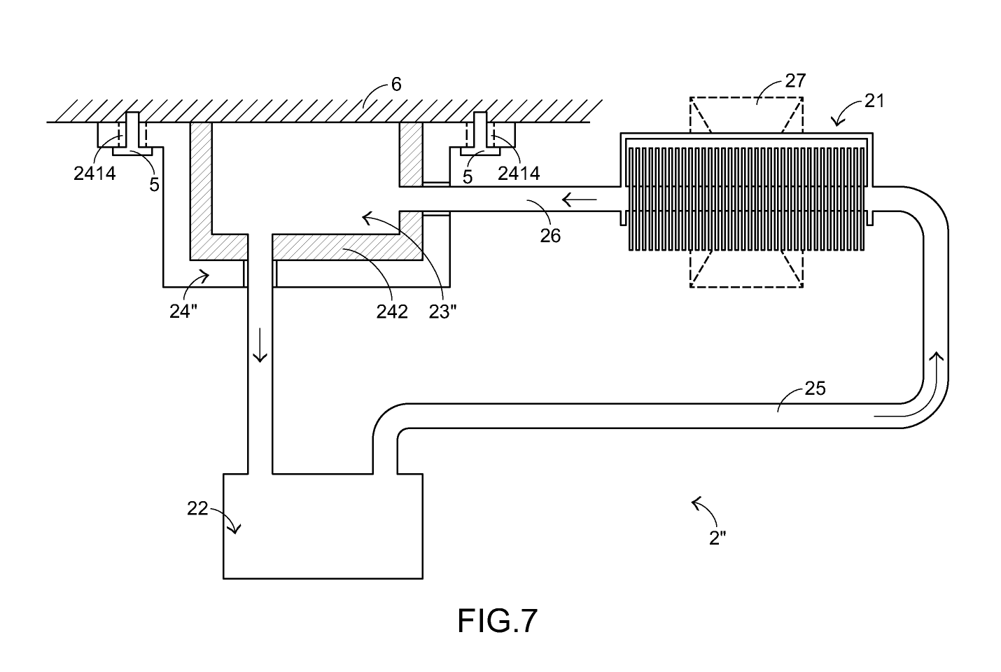

FIG. 7 schematically illustrates the architecture of a liquid-cooling heat dissipating module according to a third embodiment of the present invention. The components of the liquid-cooling heat dissipating module 2′ of this embodiment that are similar to those of the first embodiment are not redundantly described herein. In comparison with the first embodiment and the second embodiment, both of the liquid pump 23″ and the shielding cover 24″ are fixed on the an object 6 that is located outside of the liquid-cooling heat dissipating module 2″. As shown in FIG. 7, the liquid pump 23″ and the shielding cover 24″ are fixed on the same object outside the liquid-cooling heat dissipating module 2″. However, the liquid pump 23″ and the shielding cover 24″ are not restrictedly fixed on the same object.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all modifications and similar structures.

1. A liquid-cooling heat dissipating module, comprising:
a liquid-cooling radiator comprising a radiator main body, a radiator outlet and a radiator inlet;
a liquid-cooling head in thermal contact with a heat source, and comprising a head main body, a head outlet and a head inlet;
a first pipe, wherein two ends of the first pipe are connected with the head outlet of the liquid-cooling head and the radiator inlet of the liquid-cooling radiator, respectively;
a liquid pump comprising a pump main body, a pump outlet, a pump inlet and an external pump tube, wherein two ends of the external pump tube are connected with the pump outlet of the liquid pump and the head inlet of the liquid-cooling head, respectively;
a second pipe, wherein two ends of the second pipe are connected with the pump inlet of the liquid pump and the radiator outlet of the liquid-cooling radiator, respectively; and
a shielding cover, wherein at least a part of the liquid pump is sheltered by the shielding cover, so that at least a portion of a sound generated by the liquid pump is obstructed from outputting to surroundings,
wherein a chamber of the head main body, the first pipe, a chamber of the radiator main body, the second pipe, a chamber of the pump main body and the external pump tube are in fluid communication with each other to define a closed loop, and the shielding cover is isolated from and not in fluid communication with the closed loop.

2. The liquid-cooling heat dissipating module according to claim 1, wherein the shielding cover comprises a cover body and a buffering structure, wherein the buffering structure is filled in a space between the cover body and the liquid pump.

3. The liquid-cooling heat dissipating module according to claim 2, wherein the buffering structure is a sound-absorbing foam structure or a sound-insulating foam structure.

4. The liquid-cooling heat dissipating module according to claim 1, wherein the liquid pump is fixed on the liquid-cooling head.

5. The liquid-cooling heat dissipating module according to claim 4, wherein the shielding cover is fixed on the liquid-cooling head.

6. The liquid-cooling heat dissipating module according to claim 5, wherein an outer periphery of the head main body of the liquid-cooling head comprises at least one locking hole, wherein when the at least a part of the liquid pump is sheltered by the shielding cover, at least one screwing element is penetrated through the at least one locking hole and tightened into the shielding cover, so that the shielding cover is fixed on the liquid-cooling head.

7. The liquid-cooling heat dissipating module according to claim 1, wherein the shielding cover is fixed on an object that is located outside the liquid-cooling heat dissipating module.

8. The liquid-cooling heat dissipating module according to claim 7, wherein the object is an electronic component with the heat source.

9. The liquid-cooling heat dissipating module according to claim 7, wherein an outer periphery of the shielding cover comprises at least one locking hole, wherein when the at least a part of the liquid pump is sheltered by the shielding cover, at least one screwing element is penetrated through the at least one locking hole and tightened into the object, so that the shielding cover is fixed on the object.

10. The liquid-cooling heat dissipating module according to claim 1, wherein the shielding cover comprises a first opening and a second opening, wherein the external pump tube is penetrated through the first opening, and the second pipe is penetrated through the second opening.

11. The liquid-cooling heat dissipating module according to claim 10, wherein the shielding cover further comprises a third opening, and the first pipe is penetrated through the third opening.

12. The liquid-cooling heat dissipating module according to claim 1, wherein the liquid-cooling heat dissipating module further comprises a fan module, and the fan module is located beside the liquid-cooling radiator.
